(19) United States
(12) Patent Application Publication
(10) Pub. No.: US 2026/0255887 A1
(43) Pub. Date: Aug. 27, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventors: Jeong Ho Yeon, Icheon-si (KR); Min Su Kang, Icheon-si (KR); Hyun Soo Kim, Icheon-si (KR); Tae Hyung Park, Icheon-si (KR); Jeong Hoon Bae, Icheon-si (KR); Dong Yeol Yun, Icheon-si (KR); Seo Rin Cho, Icheon-si (KR); Sung Eun Choi, Icheon-si (KR); Seong Hyun Hwang, Icheon-si (KR)

(21) Appl. No.: 19/292,084

(22) Filed: Aug. 6, 2025

(30) Foreign Application Priority Data
Feb. 26, 2025 (KR) 10-2025-0025365

(51) Int. Cl. H10N 70/00; H10B 63/00

(52) U.S. Cl. CPC H10N 70/826; H10B 63/80; H10N 70/063; H10N 70/841

(57) ABSTRACT

A semiconductor device includes a first row line extending in a first direction, a first column line positioned on the first row line, and extending in a second direction that crosses the first direction, a first memory cell positioned between the first row line and the first column line, a second column line positioned on the first column line, and extending in the second direction, an interlayer insulating layer positioned between the first column line and the second column line, and a contact via connecting the first column line and the second column line by passing through the interlayer insulating layer.

### CROSS-REFERENCE TO RELATED APPLICATION

This application claims priority under 35 U.S.C. § 119 to Korean Patent Application No. 10-2025-0025365 filed on Feb. 26, 2025, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a first row line extending in a first direction, a first column line positioned on the first row line, and extending in a second direction that crosses the first direction, a first memory cell positioned between the first row line and the first column line, a second column line positioned on the first column line, and extending in the second direction, an interlayer insulating layer positioned between the first column line and the second column line, and a contact via connecting the first column line and the second column line by passing through the interlayer insulating layer.

According to an embodiment of the present disclosure, a semiconductor device may include first row lines extending in a first direction, first column lines positioned on the first row lines, and extending in a second direction that crosses the first direction, first memory cells positioned between the first row lines and the first column lines, respectively, second column lines positioned on the first column lines, and extending in the second direction, second row lines positioned on the second column lines, and extending in the first direction, second memory cells positioned between the second column lines and the second row lines, respectively, and contact vias positioned between the first column lines and the second column lines, and connecting the first column lines and the second column lines, respectively.

### BRIEF DESCRIPTION OF THE DRAWINGS

FIGS. 1A, 1B, and 1C are drawings illustrating a semiconductor device according to an embodiment of the present disclosure.

FIGS. 2A, 2B, 3A, 3B, 4A, 4B, 5A, 5B, 6A, 6B, 7A, 7B, and 7C are drawings illustrating a method of manufacturing a semiconductor device according to an embodiment of the present disclosure.

### DETAILED DESCRIPTION

Embodiments of the present disclosure provide a semiconductor device and a method of manufacturing the semiconductor device having a stable structure and an improved characteristic.

According to the present technology, a semiconductor device having a stable structure and improved reliability may be provided. As used herein, including in the claims, the term ‘or’ in a list of items (e.g., a list introduced by phrases such as ‘at least one of,’ ‘one or more of,’ or ‘one or both of’) is intended to be inclusive unless explicitly stated otherwise. Specifically, the term ‘or’ should be interpreted to cover any individual item in the list, any combination of items in the list, or all items in the list. For example, a phrase such as ‘at least one of A, B, or C’ is intended to encompass A alone, B alone, C alone, any combination of A and B, A and C, or B and C, as well as A, B, and C together. This inclusive interpretation applies unless an explicit indication to the contrary is provided in a particular context. Moreover, a first element “on” a second element indicates that the first element can be “directly on” the second element, or that at least one intervening element can be interposed between the first and second elements.

Hereinafter, some embodiments according to the technical spirit of the present disclosure are described with reference to the accompanying drawings.

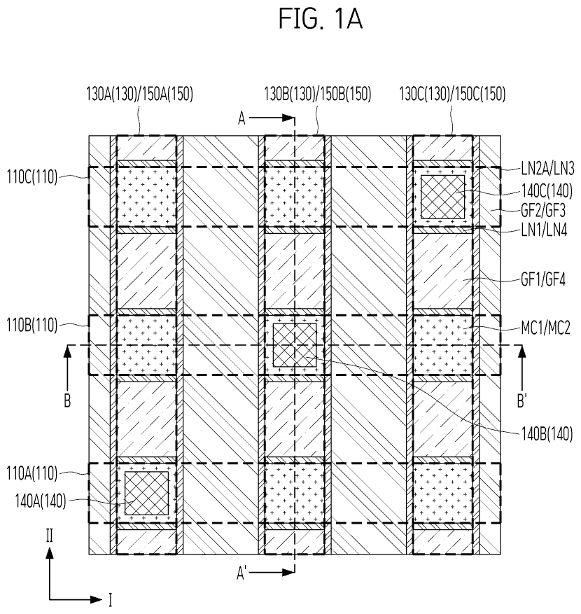

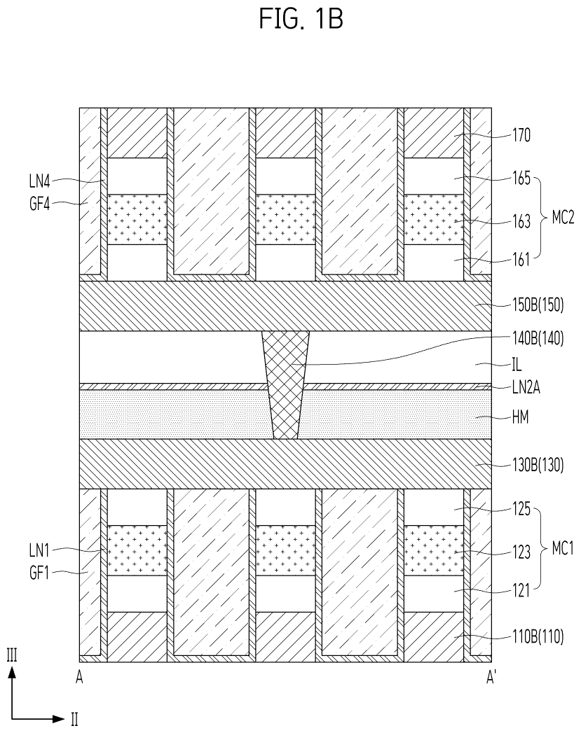

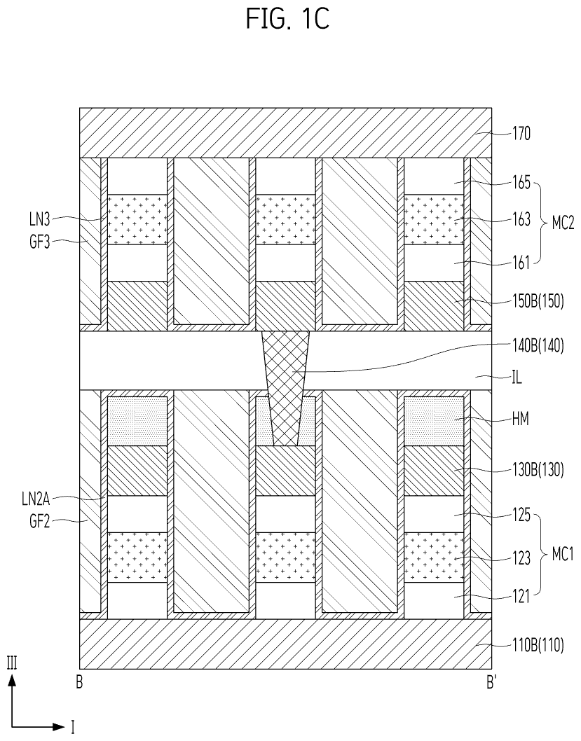

FIGS. 1A, 1B, and 1C are drawings illustrating a semiconductor device according to an embodiment of the present disclosure. FIG. 1A is a plan view, FIG. 1B is a cross-sectional view along line A-A′ of FIG. 1A, and FIG. 1C is a cross-sectional view along line B-B′ of FIG. 1A.

Referring to FIGS. 1A to 1C, the semiconductor device may include first row lines 110, second row lines 170, first column lines 130, second column lines 150, first memory cells MC1, second memory cells MC2, hard mask patterns HM, an interlayer insulating layer IL, and contact vias 140. The semiconductor device may further include first liner patterns LN1, a second liner layer LN2A, third liner patterns LN3, fourth liner patterns LN4, first gap fill patterns GF1, second gap fill patterns GF2, third gap fill patterns GF3, and fourth gap fill patterns GF4.

The first row lines 110 may extend in a first direction I. The first column lines 130 may cross the first row lines 110, and may be positioned on the first row lines 110. The first column lines 130 may extend in a second direction II crossing the first direction I. As an example, the first row lines 110 each may be a first word line, and the first column lines 130 each may be a first bit line. As another example, the first row lines 110 each may be the first bit line, and the first column lines 130 each may be the first word line. Here, the first row lines 110 and the first column lines 130 may include a conductive material such as tungsten.

The second column lines 150 may extend in the second direction II. The second column lines 150 may be positioned on the first column lines 130. The second row lines 170 may extend in the first direction I. The second row lines 170 may be positioned on the second column lines 150. As an example, the second column lines 150 may each be a second bit line, and the second row lines 170 each may be a second word line. As another example, the second column lines 150 each may be the second word line, and the second row lines 170 each may be the second bit line. Here, the second row lines 170 and the second column lines 150 may include a conductive material such as tungsten.

The first memory cells MC1 may be positioned between the first row lines 110 and the first column lines 130, respectively. The second memory cells MC2 may be positioned between the second column lines 150 and the second row lines 170, respectively. Each of the first memory cells MC1 may include a first lower electrode pattern 121, a first variable resistance pattern 123, and a first upper electrode pattern 125. Each of the second memory cells MC2 may include a second lower electrode pattern 161, a second variable resistance pattern 163, and a second upper electrode pattern 165.

The first lower electrode pattern 121 may be positioned on the first row line 110. The first lower electrode pattern 121 may be a portion of the first row line 110, or may be electrically connected to the first row line 110. The first upper electrode pattern 125 may be positioned on the first lower electrode pattern 121. The first upper electrode pattern 125 may be a portion of the first column line 130, or may be electrically connected to the first column line 130. The first variable resistance pattern 123 may be positioned between the first lower electrode pattern 121 and the first upper electrode pattern 125.

The second lower electrode pattern 161 may be positioned on the second column line 150. The second lower electrode pattern 161 may be a portion of the second column line 150, or may be electrically connected to the second column line 150. The second upper electrode pattern 165 may be positioned on the second lower electrode pattern 161. The second upper electrode pattern 165 may be a portion of the second row line 170, or may be electrically connected to the second row line 170. The second variable resistance pattern 163 may be positioned between the second lower electrode pattern 161 and the second upper electrode pattern 165.

At least one of the first lower electrode pattern 121, the first upper electrode pattern 125, the second lower electrode pattern 161, or the second upper electrode pattern 165 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, and may include a combination thereof.

At least one of the first variable resistance pattern 123 or the second variable resistance pattern 163 may be used as a data storage and as a selection element simultaneously. At least one of the first variable resistance pattern 123 or the second variable resistance pattern 163 may include a resistive material, and may have a characteristic of reversibly changing between different resistance states according to an applied voltage or current.

At least one of the first variable resistance pattern 123 or the second variable resistance pattern 163 may maintain an amorphous state during a program operation, and may not change to a crystalline state after the program operation. In other words, a phase of at least one of the first variable resistance pattern 123 or the second variable resistance pattern 163 may not change after the program operation. For example, at least one of the first variable resistance pattern 123 or the second variable resistance pattern 163 may include a variable resistance material of which a resistance changes without a phase change, and may include a chalcogenide element. At least one of the first variable resistance pattern 123 or the second variable resistance pattern 163 may include germanium (Ge), antimony (Sb), arsenic (As), silicon (Si), indium (In), tin (Sn), gallium (Ga) or the like, or may include a combination thereof.

At least one of the first variable resistance pattern 123 or the second variable resistance pattern 163 may include a phase change material, and may include a chalcogenide. At least one of the first variable resistance pattern 123 or the second variable resistance pattern 163 may include a chalcogenide glass, a chalcogenide alloy, or the like. At least one of the first variable resistance pattern 123 or the second variable resistance pattern 163 may change a phase according to the program operation. For example, at least one of the first variable resistance pattern 123 or the second variable resistance pattern 163 may have a low-resistance crystalline state by a set operation. In addition, at least one of the first variable resistance pattern 123 or the second variable resistance pattern 163 may have a high-resistance amorphous state by a reset operation. Therefore, at least one of the first variable resistance pattern 123 or the second variable resistance pattern 163 may store data in at least one of the first memory cell MC1 or the second memory cell MC2 by using a resistance difference according to the phase.

At least one of the first variable resistance pattern 123 or the second variable resistance pattern 163 may include a metal oxide (transition metal oxide), or may include a metal oxide such as a perovskite material. Therefore, data may be stored in the first and second memory cells MC1 and MC2 as an electrical path is generated or disappeared in the variable resistance pattern 123 and the second variable resistance pattern 163.

At least one of the first variable resistance pattern 123 or the second variable resistance pattern 163 may have an MTJ structure, and may include a magnetization fix layer, a magnetization free layer, and a tunnel barrier layer interposed therebetween. For example, the magnetization fix layer and the magnetization free layer may include a magnetic material, and the tunnel barrier layer may include an oxide including at least one of magnesium (Mg), aluminum (Al), zinc (Zn), or titanium (Ti). Here, a magnetization direction of the magnetization free layer may be changed by spin torque of electrons in an applied current. Therefore, data may be stored in the first memory cell MC1 according to a change in the magnetization direction of the magnetization free layer with respect to a magnetization direction of the magnetization fix layer.

In addition, at least one of the first variable resistance pattern 123 or the second variable resistance pattern 163 may have a metal insulator metal (MIM) structure including a metal oxide. In this case, data may be stored in the first memory cell MC1 or the second memory cell MC2 by using a resistance change of the metal oxide that occurs by applying a short electric pulse.

For reference, although not shown in this drawing, the semiconductor device may further include a first intermediate electrode pattern, a second intermediate electrode pattern, a first switching pattern, and a second switching pattern. For example, the semiconductor device may include a structure in which the first lower electrode pattern 121, the first switching pattern, the first intermediate electrode pattern, the first variable resistance pattern 123, and the first upper electrode pattern 125 are sequentially stacked. In addition, the semiconductor device may include a structure in which the second lower electrode pattern 161, the second switching pattern, the second intermediate electrode pattern, the second variable resistance pattern 163, and the second upper electrode pattern 165 are sequentially stacked.

In this case, the first lower electrode pattern 121, the first switching pattern, and the first intermediate electrode pattern may configure a first selection element, and the second lower electrode pattern 161, the second switching pattern, and the second intermediate electrode pattern may configure a second selection element. The first and second selection elements may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the first and second switching patterns may include a chalcogenide material.

In addition, the first intermediate electrode pattern, the first variable resistance pattern 123, and the first upper electrode pattern 125 may configure a first memory element, and the second intermediate electrode pattern, the second variable resistance pattern 163, and the second upper electrode pattern 165 may configure a second memory element. The first and second memory elements and the first and second selection elements may share the first and second intermediate electrode patterns, respectively.

The interlayer insulating layer IL may be positioned between the first memory cells MC1 and the second memory cells MC2. For example, the interlayer insulating layer IL may be positioned between the first column lines 130 and the second column lines 150. The interlayer insulating layer IL may secure an interval between the first memory cells MC1 and the second memory cells MC2. Through this, the interlayer insulating layer IL may prevent or reduce damage to the first memory cells MC1 in a process of forming the second memory cells MC2. Here, the interlayer insulating layer IL may include an insulating material such as an oxide or a nitride.

The hard mask patterns HM may be positioned on the first column lines 130, respectively. For example, each of the hard mask patterns HM may be positioned between a corresponding (e.g., contacting, or overlapping in the plan view) one of the first column lines 130 and the interlayer insulating layer IL. Here, the hard mask pattern HM may contact the first column line 130. The hard mask patterns HM may be used in a process of forming the first column lines 130 and the first memory cells MC1, and may prevent or reduce damage to the first memory cells MC1 in a process of forming the second memory cells MC2. Here, the hard mask patterns HM may include an oxide, a nitride, or the like.

The contact vias 140 may be positioned between the first column lines 130 and the second column lines 150. The contact vias 140 may be spaced apart from each other in the first direction I and the second direction II in a plane defined by the first direction I and the second direction II. For example, a contact via 140A may be positioned between a first column line 130A and a second column line 150A on a first row line 110A. A contact via 140B may be positioned between a first column line 130B and a second column line 150B on a first row line 110B. A contact via 140C may be positioned between a first column line 130C and a second column line 150C on a first row line 110C.

The contact vias 140 may connect the first column lines 130 and the second column lines 150, respectively. The contact vias 140 may connect the first column lines 130 and the second column lines 150, respectively, by passing through the interlayer insulating layer IL. Here, each of the contact vias 140 may pass through the interlayer insulating layer IL, the second liner layer LN2A, and a corresponding (e.g., abutting) one of the hard mask patterns HM. The contact vias 140 may include a conductive material such as tungsten.

The contact vias 140 may electrically connect the first column lines 130 and the second column lines 150, respectively. In other words, the first column line 130, the contact via 140, and the second column line 150 may form a current path. In this case, a total resistance of the current path may increase due to the contact via 140 compared to a case where a current path is formed by the first column line 130 and the second column line 150. In other words, because the total resistance of the current path increases, excessive application of a current to the first memory cells MC1 and the second memory cells MC2 may be prevented or reduced, and damage to the first memory cells MC1 and the second memory cells MC2 may be prevented or reduced.

For reference, although this drawing shows a case where a shape in the plane of the contact vias 140 is a quadrangle, the shape in the plane of the contact vias 140 may vary according to embodiments. For example, the shape in the plane of the contact vias 140 may be a circular shape.

The first liner patterns LN1 may cover the sidewalls adjacent in the second direction II of the first memory cells MC1. For example, the first liner patterns LN1 may cover sidewalls adjacent in the second direction II of the first memory cells MC1, and may cover sidewalls adjacent in the second direction II of the first row lines 110. Specifically, an adjacent pair of the first liner patterns LN1 in the second direction II may cover adjacent sidewalls of a corresponding (e.g., disposed therebetween) first memory cell MC1 in the second direction II. Each of the first liner patterns LN1 may extend along the first row line 110, the first lower electrode pattern 121, the first variable resistance pattern 123, and the first upper electrode pattern 125. Each of the first liner patterns LN1 may cover sidewalls of an adjacent pair of the first memory cells MC1 in the second direction II, and sidewalls of an adjacent pair of the first row lines 110 in the second direction II.

The second liner layer LN2A may cover sidewalls adjacent in the first direction I of the first memory cells MC1. For example, the second liner layer LN2A may cover sidewalls adjacent in the first direction I of the first memory cells MC1, may cover sidewalls adjacent in the first direction I of the first column lines 130, and may cover sidewalls adjacent in the first direction I of the hard mask patterns HM. Specifically, the second liner layer LN2A may cover adjacent sidewalls of the first memory cell MC1 in the first direction I, adjacent sidewalls of the first column line 130 in the first direction I, and adjacent sidewalls of the hard mask pattern HM in the first direction I. The second liner layer LN2A may extend along the first lower electrode pattern 121, the first variable resistance pattern 123, the first upper electrode pattern 125, the first column line 130, and the hard mask pattern HM. For example, the second liner layer LN2A may cover adjacent sidewalls of the first lower electrode pattern 121 in the first direction I, adjacent sidewalls of the first variable resistance pattern 123 in the first direction I, adjacent sidewalls of the first upper electrode pattern 125 in the first direction I, adjacent sidewalls of the first column line 130 in the first direction I, and adjacent sidewalls of the hard mask pattern HM in the first direction I. In addition, the second liner layer LN2A may extend between the hard mask patterns HM and the interlayer insulating layer IL. The second liner layer LN2A may further extend on a portion of the first row line 110 between an adjacent pair of the first memory cells MC1 in the first direction I.

The third liner patterns LN3 may cover sidewalls adjacent in the first direction I of the second memory cells MC2. For example, the third liner patterns LN3 may cover sidewalls adjacent in the first direction I of the second memory cells MC2, and may cover sidewalls adjacent in the first direction I of the second column lines 150. Specifically, an adjacent pair of the third liner patterns LN3 in the first direction I may cover adjacent sidewalls of a corresponding (e.g., disposed therebetween) second memory cell MC2 in the first direction I. Each of the third liner patterns LN3 may extend along the second lower electrode pattern 161, the second variable resistance pattern 163, and the second upper electrode pattern 165.

The fourth liner patterns LN4 may cover sidewalls adjacent in the second direction II of the second memory cells MC2. For example, the fourth liner patterns LN4 may cover sidewalls adjacent in the second direction II of the second memory cells MC2, and may cover sidewalls adjacent in the second direction II of the second row lines 170. Specifically, an adjacent pair of the fourth liner patterns LN4 in the second direction II may cover adjacent sidewalls of a corresponding (e.g., disposed therebetween) second memory cell MC2 in the second direction II. Each of the fourth liner patterns LN4 may extend along the second lower electrode pattern 161, the second variable resistance pattern 163, the second upper electrode pattern 165, and the second low line 170.

The first liner patterns LN1 and the second liner layer LN2A may protect the first memory cells MC1 in a process of manufacturing the semiconductor device. The third liner patterns LN3 and the fourth liner patterns LN4 may protect the second memory cells MC2 in the process of manufacturing the semiconductor device. At least one of the first liner patterns LN1, the second liner layer LNA, the third liner patterns LN3, or the fourth liner patterns LN4 may include a nitride.

The first gap fill patterns GF1 may be positioned between the first memory cells MC1 adjacent in the second direction II, and may be positioned on the first liner patterns LN1. In other words, the first liner patterns LN1 may be positioned between the first gap fill patterns GF1 and the first memory cells MC1. The first gap fill patterns GF1 may include an insulating material such as an oxide.

The second gap fill patterns GF2 may be positioned between the first memory cells MC1 adjacent in the first direction I, and may be positioned on the second liner layer LN2A. In other words, the second liner layer LN2A may be positioned between the second gap fill patterns GF2 and the first memory cells MC1. The second gap fill patterns GF2 may include an insulating material such as an oxide.

The third gap fill patterns GF3 may be positioned between the second memory cells MC2 adjacent in the first direction I, and may be positioned on the third liner patterns LN3. In other words, the third liner patterns LN3 may be positioned between the third gap fill patterns GF3 and the second memory cells MC2. The third gap fill patterns GF3 may include an insulating material such as an oxide.

The fourth gap fill patterns GF4 may be positioned between the second memory cells MC2 adjacent in the second direction II, and may be positioned on the fourth liner patterns LN4. In other words, the fourth liner patterns LN4 may be positioned between the fourth gap fill patterns GF4 and the second memory cells MC2. The fourth gap fill patterns GF4 may include an insulating material such as an oxide.

According to the structure described above, a physical distance between the first memory cells MC1 and the second memory cells MC2 may be secured through the hard mask patterns HM and the interlayer insulating layer IL, thereby protecting the first memory cells MC1 and/or the second memory cells MC2. For example, such a distance between the first memory cells MC1 and the second memory cells MC2 may be sufficiently large to substantially prevent damage to the first memory cells MC1 while forming the second memory cells MC2.

In addition, according to an embodiment of the present disclosure, the first column lines 130 and the second column lines 150 may be electrically connected through the contact vias 140. In this case, the total resistance of the current path may increase compared to the case where the current path is formed by the first column line 130 and the second column line 150 without the contact vias 140, and thus excessive application of a current to the first memory cells MC1 and/or the second memory cells MC2 may be substantially prevented. Therefore, the contact vias 140 may substantially prevent the first memory cells MC1 and/or the second memory cells MC2 from being damaged.

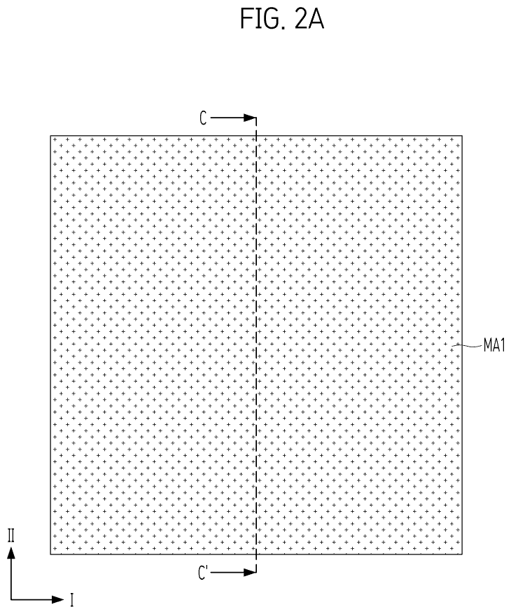

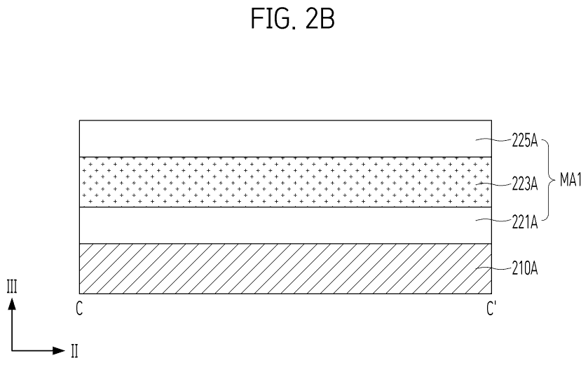

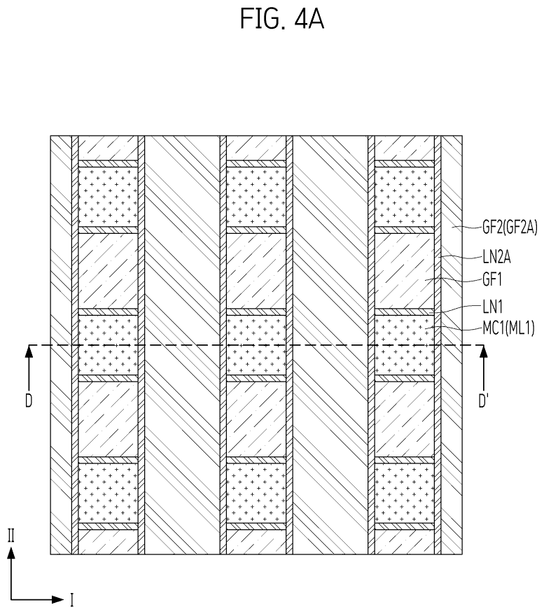

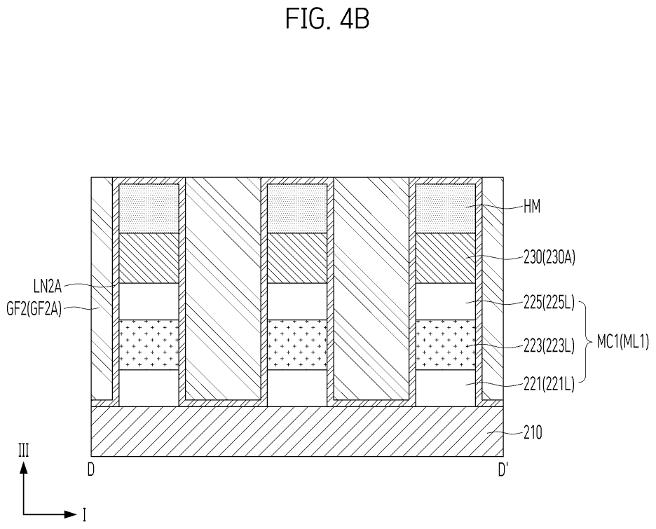

FIGS. 2A, 2B, 3A, 3B, 4A, 4B, 5A, 5B, 6A, 6B, 7A, 7B, and 7C are drawings illustrating a method of manufacturing a semiconductor device according to an embodiment of the present disclosure. FIGS. 2A, 3A, 4A, 5A, 6A, and 7A are plan views, FIGS. 2B, 3B, and 7C are cross-sectional views along line C-C′ of FIGS. 2A, 3A, and 7A, respectively, and FIGS. 4B, 5B, 6B, and 7B are cross-sectional views alone line D-D′ of FIGS. 4A, 5A, 6A, and 7A, respectively. Hereinafter, contents that overlap the contents described above may be omitted for the interest of brevity.

Referring to FIGS. 2A and 2B, a first memory layer MA1 may be formed on a first conductive layer 210A. For example, the first memory layer MA1 may be formed sequentially stacking a first lower electrode layer 221A, a first variable resistance layer 223A, and a first upper electrode layer 225A on the first conductive layer 210A. Here, the first conductive layer 210A may include a conductive material such as tungsten.

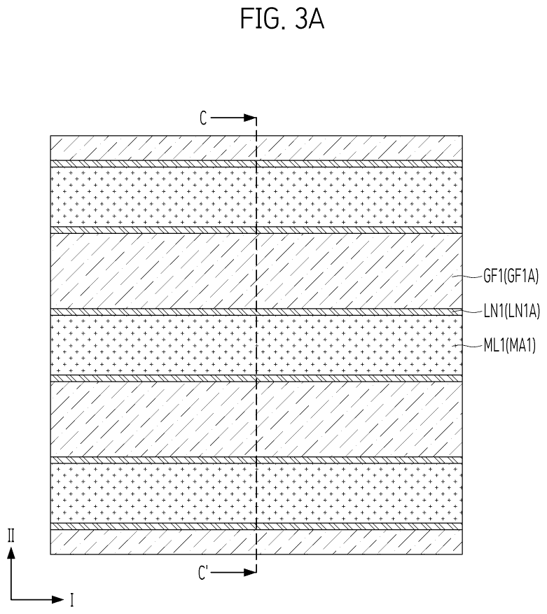

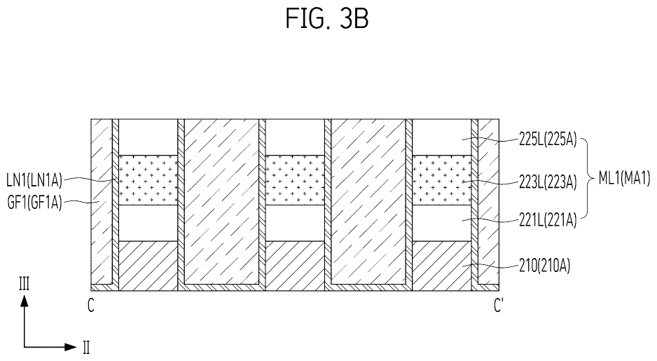

Referring to FIGS. 3A and 3B, first memory lines ML1 extending in the first direction I may be formed by etching the first memory layer MA1. For example, the first memory lines ML1 including first upper electrode lines 225L, first variable resistance lines 223L, and first lower electrode lines 221L may be formed by sequentially etching the first upper electrode layer 225A, the first variable resistance layer 223A, and the first lower electrode layer 221A.

Subsequently, first row lines 210 extending in the first direction I may be formed by etching the first conductive layer 210A. Here, each of the first row lines 210 may be a bit line or a word line.

Subsequently, a first liner layer LN1A covering sidewalls adjacent in the second direction II crossing the first direction I of the first memory lines ML1 may be formed. Specifically, a first liner layer LN1A may cover top surfaces and adjacent sidewalls of the first memory lines ML1 in the second direction II, and cover adjacent sidewalls of the first row lines 210 in the second direction II. For example, the first liner layer LN1A may be formed conformally along a profile of the first row lines 210 and the first memory lines ML1. Here, the first liner layer LN1A may include an insulating material such as a nitride.

Subsequently, a first gap fill layer GF1A may be formed on the first liner layer LN1A. For example, the first gap fill layer GF1A may be formed to fill spaces between the first memory lines ML1 adjacent in the second direction II. Here, the first gap fill layer GF1A may include an insulating material such as an oxide.

Subsequently, the first gap fill layer GF1A and the first liner layer LN1A may be etched so that the first memory lines ML1 are exposed. For example, the first gap fill layer GF1A and the first liner layer LN1A may be planarized so that the first upper electrode lines 225L are exposed. Here, the first gap fill layer GF1A may be separated into first gap fill patterns GF1, and the first liner layer LN1A may be separated into first liner patterns LN1.

Referring to FIGS. 4A and 4B, first column lines 230 extending in the second direction II may be formed on the first row lines 210. First, a second conductive layer 230A may be formed on the first memory lines ML1. Subsequently, hard mask patterns HM extending in the second direction II may be formed on the second conductive layer 230A. Here, the hard mask patterns HM may be formed to correspond to positions where the first column lines 230 are to be formed. The hard mask patterns HM may include an oxide, a nitride, or the like. Subsequently, the first column lines 230 may be formed by etching the second conductive layer 230A by using the hard mask patterns HM as an etching barrier. Here, each of the first column lines 230 may be a bit line or a word line.

Subsequently, the first memory cells MC1 may be formed between the first row lines 210 and the first column lines 230, respectively. For example, the first memory cells MC1 including first upper electrode patterns 225, first variable resistance patterns 223, and first lower electrode patterns 221 may be formed by etching the first upper electrode lines 225L, the first variable resistance lines 223L, and the first lower electrode lines 221L.

Subsequently, the second liner layer LN2A covering sidewalls adjacent in the first direction I of the first memory cells MC1 may be formed. For example, the second liner layer LN2A may be formed conformally along a profile of the first memory cells MC1 and the first column lines 230. In other words, the second liner layer LN2A may cover adjacent sidewalls of the first memory cells MC1 in the first direction I, adjacent sidewalls of the first column lines 230 in the first direction I, and adjacent sidewalls of the hard mask patterns HM in the first direction I. Here, the second liner layer LN2A may include an insulating material such as a nitride.

Subsequently, a second gap fill layer GF2A may be formed on the second liner layer LN2A. For example, the second gap fill layer GF2A may be formed to fill spaces between the first memory cells MC1 adjacent in the first direction I. Here, the second gap fill layer GF2A may include an insulating material such as an oxide.

Subsequently, the second gap fill layer GF2A may be etched so that the second liner layer LN2A is exposed. For example, the second gap fill layer GF2A may be planarized so that the second liner layer LN2A is exposed. Here, the second gap fill layer GF2A may be separated into second gap fill patterns GF2.

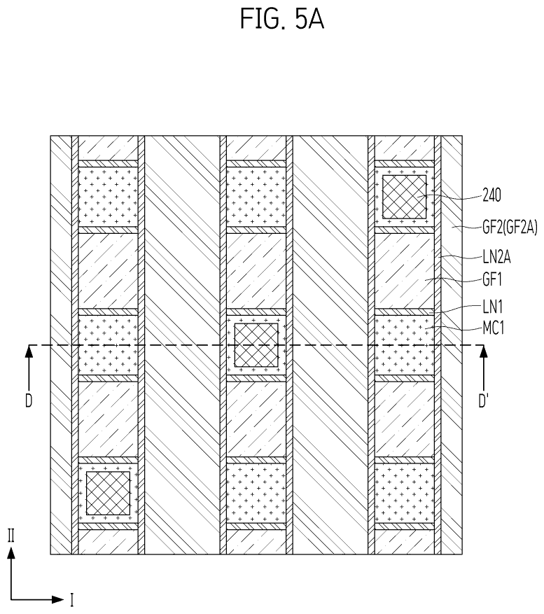

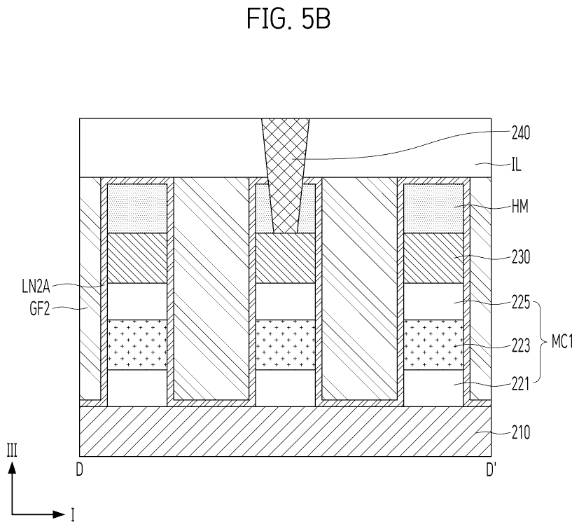

Referring to FIGS. 5A and 5B, an interlayer insulating layer IL may be formed on the first column lines 230. For example, the interlayer insulating layer IL may be formed on the second liner layer LN2A and the second gap fill patterns GF2. Here, the second liner layer LN2A may extend between the hard mask patterns HM and the interlayer insulating layer IL. The interlayer insulating layer IL may include an insulating material such as an oxide.

Subsequently, contact vias 240 respectively connected to the first column lines 230 by passing through the interlayer insulating layer IL may be formed. For example, the contact vias 240 passing through the interlayer insulating layer IL, the second liner layer LN2A, and the hard mask pattern HM may be formed. Here, the contact vias 240 may include a conductive material such as tungsten.

The contact vias 240 may be formed to be spaced apart from each other in the first direction I and the second direction II. For example, the contact vias 240 may be formed to be spaced apart from each other in a diagonal direction. When the contact vias are formed at positions adjacent in either the first direction I or the second direction II, the first memory cells adjacent in either the first direction I or the second direction II formed positions corresponding to the contact vias may be damaged in a process of forming the contact vias. However, according to an embodiment of the present disclosure, because the contact vias 240 may be formed to be spaced apart from each other in both of the first direction I and the second direction II (e.g., a diagonal direction in FIG. 5A), a distance between adjacent contact vias 240 may be sufficiently large to prevent or significantly reduce damage to the first memory cells MC1 in the process of forming the contact vias 240.

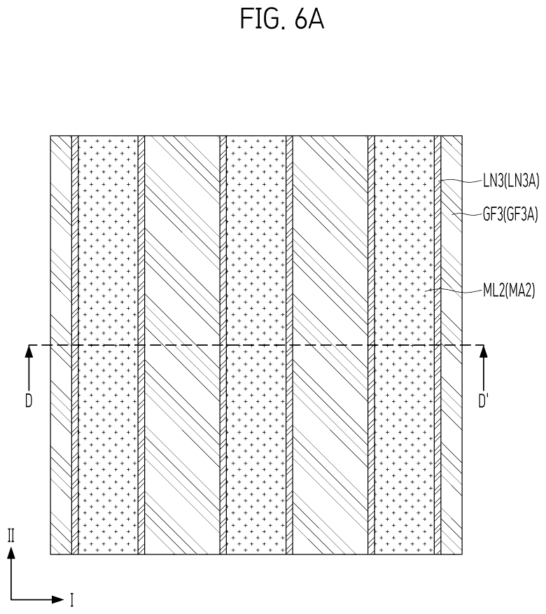

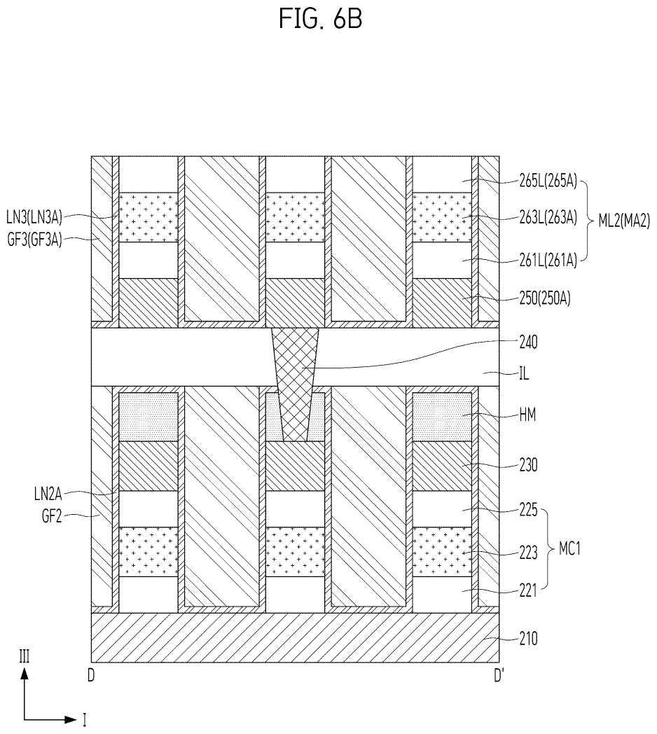

Referring to FIGS. 6A and 6B, a third conductive layer 250A may be formed on the contact vias 240 and the interlayer insulating layer IL. Here, the third conductive layer 250A may include a conductive material such as tungsten.

Subsequently, a second memory layer MA2 may be formed on the third conductive layer 250A. For example, the second memory layer MA2 may be formed by sequentially stacking a second lower electrode layer 261A, a second variable resistance layer 263A, and a second upper electrode layer 265A on the third conductive layer 250A.

Subsequently, second memory lines ML2 extending in the second direction II may be formed by etching the second memory layer MA2. For example, the second memory lines ML2 including second upper electrode lines 265L, second variable resistance lines 263L, and second lower electrode lines 261L may be formed by sequentially etching the second upper electrode layer 265A, the second variable resistance layer 263A, and the second lower electrode layer 261A.

Subsequently, second column lines 250 extending in the second direction II may be formed by etching the third conductive layer 250A. For example, the second column lines 250 extending in the second direction II may be formed on the contact vias 240. Here, the contact vias 240 may connect the first column lines 230 and the second column lines 250, respectively. In other words, the contact vias 240 may electrically connect the first column lines 230 and the second column lines 250, respectively.

In a process of forming the second column lines 250 by etching the third conductive layer 250A, a portion of the interlayer insulating layer IL may be etched together. For example, a portion may be etched from an upper surface of the interlayer insulating layer IL. In other words, if an interlayer insulating layer did not exist, the first column lines 230 and/or the first memory cells MC1 would likely be damaged in a process of forming the second column lines 250. According to an embodiment of the present disclosure, by forming the interlayer insulating layer IL between the first column lines 230 and the second column lines 250, a physical distance may be secured between the first column lines 230 and the second column lines 250, and thus damage to the first column lines 230 and/or the first memory cells MC1 may be prevented or reduced in a process of forming the second column lines 250.

In addition, according to an embodiment of the present disclosure, the first column lines 230 and the second column lines 250 may be electrically connected through the contact vias 240. If the contact vias 240 were not formed, the first column lines 230 would need to be exposed to electrically connect the first column lines 230 and the second column lines 250. In other words, in the absence of the contact vias 240, the hard mask patterns HM and the second liner layer LN2A formed on the first column lines 230 would need to be removed. In this case, the first column lines 230 would likely be damaged in a process of removing the hard mask patterns HM and the second liner layer LN2A. However, according to an embodiment of the present disclosure, because the first column lines 230 and the second column lines 250 formed to be spaced apart from each other may be electrically connected through the contact vias 240, there is no need to remove the hard mask patterns HM and the second liner layer LN2A so that the first column lines 230 are exposed. In other words, damage that may occur to the first column lines 230 in a process of removing the hard mask patterns HM and the second liner layer LN2A may be prevented or reduced. In addition, according to an embodiment of the present disclosure, by causing the hard mask patterns HM and the second liner layer LN2A to remain, the first memory cells MC1 may be substantially prevented from being damaged in a process of forming the second column lines 250, the second memory lines ML2, a process of forming the second memory cells in a subsequent process, and/or the like.

Subsequently, a third liner layer LN3A covering sidewalls adjacent in the first direction I of the second memory lines ML2 may be formed. For example, the third liner layer LN3A may be formed conformally along a profile of the second column lines 250 and the second memory lines ML2. Specifically, the third liner layer LN3A may cover adjacent sidewalls of the second memory lines ML2 in the first direction I and adjacent sidewalls of the second column lines 250 in the first direction I. Here, the third liner layer LN3A may include an insulating material such as a nitride.

Subsequently, a third gap fill layer GF3A may be formed on the third liner layer LN3A. For example, the third gap fill layer GF3A may be formed to fill spaces between the second memory lines ML2 adjacent in the first direction I. Here, the third gap fill layer GF3A may include an insulating material such as an oxide.

Subsequently, the third gap fill layer GF3A and the third liner layer LN3A may be etched so that the second memory lines ML2 are exposed. For example, the third gap fill layer GF3A and the third liner layer LN3A may be planarized so that the second memory lines ML2 are exposed. In this process, the third gap fill layer GF3A may be separated into third gap fill patterns GF3, and the third liner layer LN3A may be separated into third liner patterns LN3.

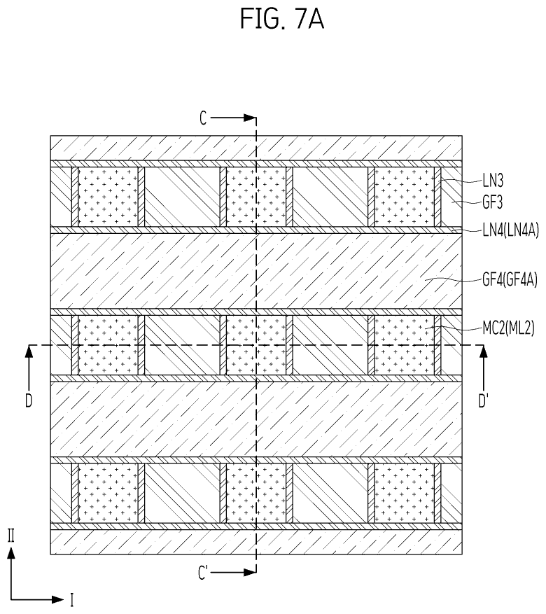

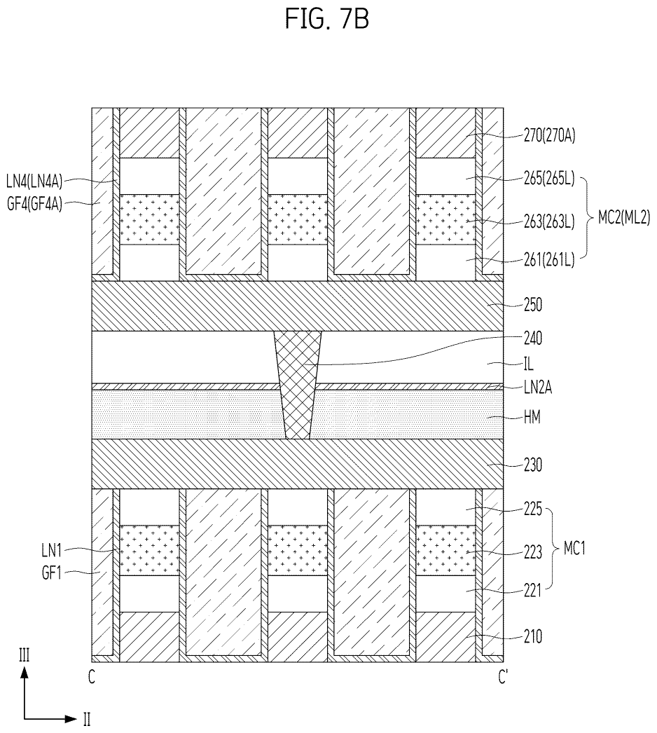

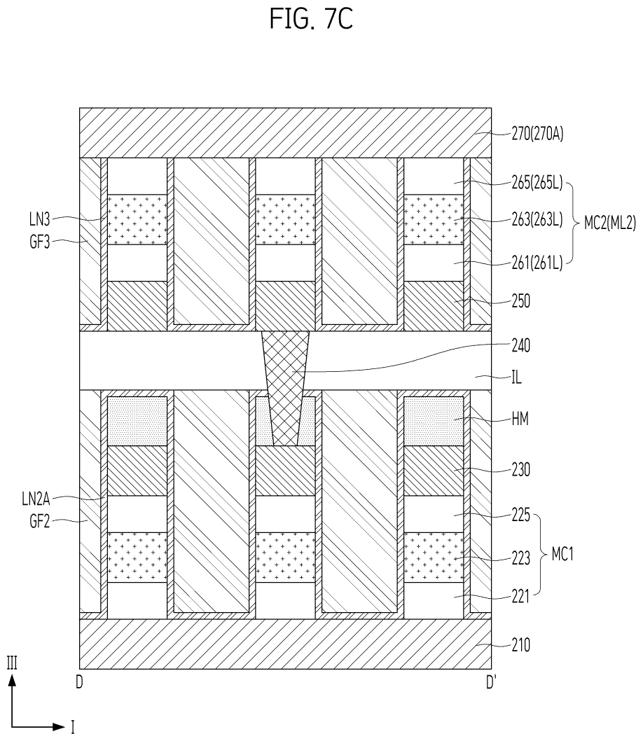

Referring to FIGS. 7A to 7C, second row lines 270 extending in the first direction I may be formed on the second column lines 250. First, a fourth conductive layer 270A may be formed on the second memory lines ML2. Here, the fourth conductive layer 270A may include a conductive material such as tungsten. Subsequently, the second row lines 270 extending in the first direction I may be formed by etching the fourth conductive layer 270A.

Subsequently, second memory cells MC2 may be formed by etching the second memory lines ML2. For example, the second memory cells MC2 including second upper electrode patterns 265, second variable resistance patterns 263, and second lower electrode patterns 261 may be formed by etching the second upper electrode lines 265L, the second variable resistance lines 263L, and the second lower electrode lines 261L.

Subsequently, a fourth liner layer LN4A covering sidewalls adjacent in the second direction II of the second memory cells ML2 may be formed. For example, the fourth liner layer LN4A may be formed conformally along a profile of the second row lines 270 and the second memory cells MC2. Specifically, the fourth liner layer LN4A may cover adjacent sidewalls of the second row lines 270 in the second direction II and adjacent sidewalls of the second memory cells MC2 in the second direction II. Here, the fourth liner layer LN4A may include an insulating material such as a nitride.

Subsequently, a fourth gap fill layer GF4A may be formed on the fourth liner layer LN4A. For example, the fourth gap fill layer GF4A may be formed to fill spaces between the second memory cells MC2 adjacent in the second direction II. Here, the fourth gap fill layer GF4A may include an insulating material such as an oxide.

Subsequently, the fourth gap fill layer GF4A and the fourth liner layer LN4A may be etched so that the second row lines 270 are exposed. For example, the fourth gap fill layer GF4A and the fourth liner layer LN4A may be planarized so that the second row lines 270 are exposed. In this process, the fourth gap fill layer GF4A may be separated into fourth gap fill patterns GF4, and the fourth liner layer LN4A may be separated into third liner patterns LN4.

According to an embodiment of the present disclosure, the contact vias 240 connecting the first column lines 230 and the second column lines 250 may be formed. The first column line 230, the contact via 240, and the second column line 250 may form a current path. In this case, the total resistance of the current path may increase due to the contact via 240 compared to the case where the current path is formed by the first column line 230 and the second column line 250 without the contact via 240. In other words, because the total resistance of the current path increases, excessive application of a current to the first memory cells MC1 and the second memory cells MC2 may be prevented or reduced, and damage to the first memory cells MC1 and the second memory cells MC2 may be prevented or reduced.

For reference, in this specification, a case where the first column lines 230 and the first memory cells MC1 are formed using the hard mask patterns HM is described, but embodiments of the present disclosure are not limited thereto. In some embodiments, the hard mask patterns may be used in a process of forming the first row lines 210, the first memory lines ML1, the second column lines 250, the second memory lines ML2, the second row lines 270 and/or the second memory cells MC2.

For example, the hard mask patterns may be formed in consideration of a position where the first memory lines ML1 and the first row lines 210 are to be formed on the first memory layer MA1. The first memory lines ML1 and the first row lines 210 may be formed by etching the first memory layer MA1 and the first conductive layer 210A by using the hard mask patterns as an etching barrier. Subsequently, the hard mask patterns may be removed.

Similarly, the hard mask patterns may be used in a process of forming the second column lines 250, the second memory lines ML2, the second row lines 270, and/or the second memory cells MC2, and the hard mask patterns used here may be removed.

According to the manufacturing method described above, the interlayer insulating layer IL may be formed on the first column lines 230 before forming the second column lines 250. In this case, a physical distance may be secured between the first column lines 230 and the second column lines 250, and thus the first column lines 230 may be substantially prevented from being damaged in a process of forming the second column lines 250. In addition, by remaining the hard mask patterns HM and the second liner layer LN2A formed on the first column lines 230, the first memory cells MC1 may be substantially prevented from being damaged in a subsequent process.

In addition, the first column lines 230 and the second column lines 250 may be electrically connected through the contact vias 240. In this case, the total resistance of the current path including the first column line 230, the contact via 240, and the second column line 250 may increase, and thus excessive application of a current to the first memory cells MC1 and/or the second memory cells MC2 may be substantially prevented. Therefore, the contact vias 140 may substantially prevent the first memory cells MC1 and/or the second memory cells MC2 from being damaged.

Although some embodiments of the present disclosure have been described with reference to the accompanying drawings, various embodiments of the present disclosure are not limited to the above-described embodiments. Various forms of substitution, modification, and change of the embodiments will be possible by those skilled in the art to which the present disclosure belongs, and these also belong to embodiments of the present disclosure.

What is claimed is:

1. A semiconductor device comprising:
a first row line extending in a first direction;
a first column line positioned on the first row line, and extending in a second direction that crosses the first direction;
a first memory cell positioned between the first row line and the first column line;
a second column line positioned on the first column line, and extending in the second direction;
an interlayer insulating layer positioned between the first column line and the second column line; and
a contact via connecting the first column line and the second column line by passing through the interlayer insulating layer.

2. The semiconductor device of claim 1, further comprising:
a hard mask pattern positioned between the first column line and the interlayer insulating layer.

3. The semiconductor device of claim 2, further comprising:
a second liner layer covering adjacent sidewalls of the first memory cell in the first direction.

4. The semiconductor device of claim 3, wherein the second liner layer covers adjacent sidewalls of the first column line in the first direction and adjacent sidewalls of the hard mask pattern in the first direction.

5. The semiconductor device of claim 3, wherein the second liner layer extends between the hard mask pattern and the interlayer insulating layer.

6. The semiconductor device of claim 3, wherein the contact via passes through the interlayer insulating layer, the second liner layer, and the hard mask pattern.

7. The semiconductor device of claim 3, further comprising:
second gap fill patterns positioned between a plurality of memory cells adjacent in the first direction, the plurality of memory cells including the first memory cell, the second gap fill patterns being positioned on the second liner layer.

8. The semiconductor device of claim 1, further comprising:
first liner patterns covering adjacent sidewalls of the first memory cell in the second direction; and
first gap fill patterns positioned between a plurality of memory cells adjacent in the second direction, the plurality memory cells including the first memory cell, the first gap fill patterns being positioned on the first liner patterns.

9. The semiconductor device of claim 1, further comprising:
a second row line positioned on the second column line, and extending in the first direction; and
a second memory cell positioned between the second column line and the second row line.

10. The semiconductor device of claim 9, further comprising:
third liner patterns covering adjacent sidewalls of the second memory cell in the first direction; and
third gap fill patterns positioned between a plurality of memory cells adjacent in the first direction, the plurality of memory cells including the second memory cell, the third gap fill patterns being positioned on the third liner patterns.

11. The semiconductor device of claim 9, further comprising:
fourth liner patterns covering adjacent sidewalls of the second memory cell in the second direction.

12. The semiconductor device of claim 11, further comprising:
fourth gap fill patterns positioned between a plurality of memory cells adjacent in the second direction, the plurality of memory cell including the second memory cell, the fourth gap fill patterns being positioned on the fourth liner patterns.

13. A semiconductor device comprising:
first row lines extending in a first direction;
first column lines positioned on the first row lines, and extending in a second direction that crosses the first direction;
first memory cells positioned between the first row lines and the first column lines, respectively;
second column lines positioned on the first column lines, and extending in the second direction;
second row lines positioned on the second column lines, and extending in the first direction;
second memory cells positioned between the second column lines and the second row lines, respectively; and
contact vias positioned between the first column lines and the second column lines, and connecting the first column lines and the second column lines, respectively.

14. The semiconductor device of claim 13, wherein each of the contact vias is spaced apart from each other in the first direction and the second direction.

15. The semiconductor device of claim 13, further comprising:
an interlayer insulating layer positioned between the first column lines and the second column lines.

16. The semiconductor device of claim 15, further comprising:
hard mask patterns positioned between the first column lines and the interlayer insulating layer.

17. The semiconductor device of claim 16, further comprising:
a second liner layer covering adjacent sidewalls of the first memory cells in the first direction.

18. The semiconductor device of claim 17, wherein the second liner layer covers adjacent sidewalls of the first column lines in the first direction, and
wherein the second liner layer covers adjacent sidewalls of the hard mask patterns in the first direction.

19. The semiconductor device of claim 17, wherein the second liner layer extends between the hard mask patterns and the interlayer insulating layer.

20. The semiconductor device of claim 17, wherein each of the contact vias passes through the interlayer insulating layer, the second liner layer, and a corresponding one of the hard mask patterns.

21. The semiconductor device of claim 15, wherein the contact vias connect the first column lines and the second column lines, respectively, by passing through the interlayer insulating layer.

22. The semiconductor device of claim 13, further comprising:
first liner patterns covering adjacent sidewalls of the first memory cells in the second direction.
